(19) United States
(12) Patent Application Publication
(10) Pub. No.: US 2006/0118851 A1
(43) Pub. Date: Jun. 8, 2006

(54) Memory cell and integrated memory circuit

(76) Inventors: Marc Strasser, Munchen (DE); Bjoern Fischer, Munchen (DE); Ralph Stoemmer, Neubiberg (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/240,422

(22) Filed: Sep. 30, 2005

(30) Foreign Application Priority Data
Sep. 30, 2004 (DE) 102004047665.9-33

(51) Int. Cl. H01L 29/94

(52) U.S. Cl. 257/301

(57) ABSTRACT

A memory cell is provided for storing a bit. The memory cell includes a capacitor with capacitor electrodes for storing electric charge and a semiconductor switch with a channel region, the electrical conductivity of which is controllable, for connecting the capacitor to a bit line, via which a bit can be written to and read from the memory cell. The channel region and a metallic terminal region connected to one of the capacitor electrodes form a metal-semiconductor junction.

### CROSS-REFERENCE TO RELATED APPLICATIONS

This application claims foreign priority benefits under 35 U.S.C. § 119 to co-pending German patent application number DE 10 2004 047 665.9-33, filed 30 Sep. 2004. This related patent application is herein incorporated by reference in its entirety.

### BACKGROUND OF THE INVENTION

1. Field of the Invention

The present invention relates to a memory cell for storing a bit, to an integrated semiconductor circuit having a memory cell and to an integrated memory circuit having a plurality of memory cells.

2. Description of the Related Art

A dynamic memory cell or a memory cell of a dynamic random access memory (DRAM) comprises a capacitor, the charge state of which represents the value (0 or 1) of a bit, and a transistor. The transistor is generally a field-effect transistor, in particular a metal oxide semiconductor (MOS) transistor. The transistor or its channel and the capacitor are connected in series. To write or read the content of the memory cell, the transistor is switched on or made conductive, in order to enable the capacitor to be charged or discharged or to enable the charge state of the capacitor to be recorded or scanned.

Large scale integrated memory circuits include one or more arrays of memory cells of this type. The transistor and the capacitor of each memory cell are connected to one another via a semiconductor region which is highly doped at the capacitor in order to form a low-resistance connection to one of the two capacitor electrodes. At the side or end which is remote from the capacitor, the semiconductor region merges into the drain electrode of the transistor and is correspondingly doped.

The ability of a memory cell to keep an item of information stored in it readable and the refresh time or retention time, after which the charge stored in the capacitor has to be refreshed, are dependent to a significant extent, inter alia, on the blocking properties of the transistor. Therefore, the aim is to achieve the highest possible resistance and the lowest possible leakage current for the transistor in the off state. For this purpose, the electric field in the transistor, in particular in the abovementioned semiconductor region and in the channel region, must not exceed a critical value. This results in a minimum length of these regions for a given voltage.

With a view to maximizing the storage density, which in turn constitutes an important cost factor, all the dimensions of DRAM memory cells need to be reduced. However, the voltages used in memory cells will continue to remain substantially unchanged in the future. Consequently, the abovementioned minimum length of the semiconductor region between capacitor and transistor cannot be reduced further. This represents a considerable obstacle to further miniaturization of memory cells.

The article “A new Route to Zero-Barrier Metal Source/Drain MOSFETs” by Daniel Connelly et al. (IEEE Journal of Nanoelectronics, 2003 Silicon Nanoelectronics Workshop, Jun. 8-9, 2003, Rihga Royal Hotel, Kyoto, Japan) describes a reduction in the resistance of the Schottky barrier at a metal-silicon interface by arranging an ultra-thin insulator between metal and silicon.

The article “High-Performance P-Channel Schottky-Barrier SOI FinFET Featuring Self-Aligned PtSi Source/Drain and Electrical Junctions” by H. C. Lin et al. (IEEE Electron device letters, volume 24, No. 2, February 2003) describes a Schottky-barrier MOS transistor in which metal silicide is used as source electrode and drain electrode.

### SUMMARY OF THE INVENTION

The object of the present invention is to provide a memory cell, an integrated semiconductor circuit and an integrated memory circuit which allow further integration and miniaturization.

The present invention is based on the idea of arranging a metallic terminal region, which is electrically conductively connected to a capacitor electrode of a memory cell, and the channel region of a semiconductor switch of the memory cell in such a way that they form a metal-semiconductor junction. For this purpose, the metallic terminal region and the channel region directly adjoin one another, or only a thin tunnel barrier layer is arranged between them.

One advantage of the present invention is that a considerable space saving is achieved by the elimination of a doped semiconductor region or a source or drain electrode between the channel region and the metallic terminal region.

A further advantage is that the choice of metal to form the terminal region allows the electron work function and the dielectric constant to be substantially matched. These additional degrees of freedom can readily be utilized to achieve an improvement to the memory cell, in particular to lengthen its refresh time.

A further advantage is that a reduced series resistance of the capacitor allows faster charging and discharging of the capacitor and therefore faster writing of the memory cell.

Another advantage is that the memory cell, in particular the metallic terminal region, can be produced self-aligned with respect to the gate electrode and therefore at a minimum distance from it and without any fluctuations in this distance.

The tunnel barrier layer, which is preferably provided between the metallic terminal region and the channel region, allows ON currents (in the switched-on state) and OFF currents (in the switched-off state) to be optimized, and therefore also allows faster writing and reading of the memory cell. Moreover, a tunnel barrier layer acts as a diffusion barrier for dopant from the channel region.

It is preferable for the metallic terminal region and one of the capacitor electrodes to be formed integrally or as a single piece or homogenously, and in particular, it is preferable for a section of the metallic capacitor electrode which is laterally adjacent to the channel region to simultaneously form the terminal region.

The electrical conductivity of the channel region is preferably controlled by a gate electrode which is insulated from the channel region by an insulator layer. The edge of the gate electrode may be arranged above the metal-semiconductor junction. However, it is preferable for the gate electrode to be laterally spaced apart from the metal-semiconductor junction, allowing lower leakage currents to be achieved. Alternatively, the gate electrode overlaps the metallic terminal region, in order to achieve better potential passage.

In the context of the present patent application, metal-semiconductor compounds which have metallic properties, for example, metal silicides, are also considered to be metallic.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a diagrammatic sectional illustration of a memory cell in accordance with an exemplary embodiment of the present invention;

FIG. 2 shows a diagrammatic sectional illustration of a memory cell in accordance with a variant of the exemplary embodiment shown in FIG. 1; and

FIG. 3 diagrammatically depicts an integrated memory circuit in accordance with a further exemplary embodiment of the present invention.

### DETAILED DESCRIPTION OF THE PREFERRED EMBODIMENT

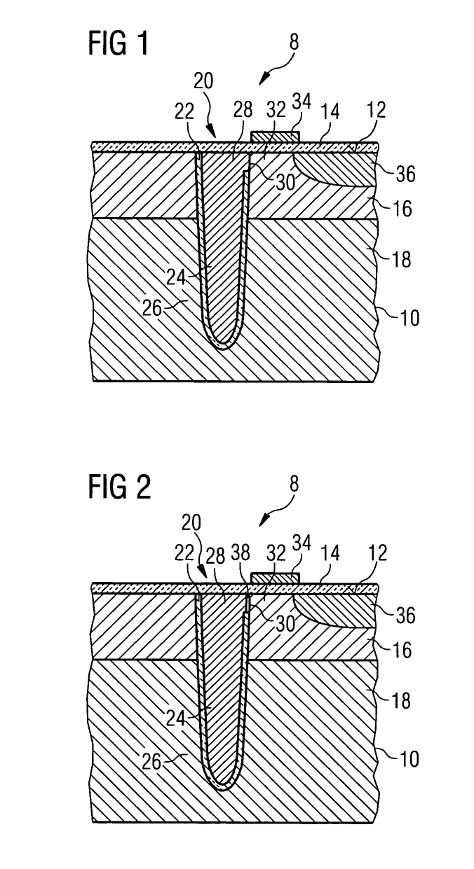

FIG. 1 diagrammatically depicts a vertical section through a memory cell 8 in accordance with an exemplary embodiment of the present invention and illustrates an excerpt or part of a substrate 10 in which the memory cell 8 is arranged. An insulator layer 14 is arranged on a surface 12 of the substrate 10. The substrate 10 substantially comprises a p-doped layer 16 beneath the surface 12 and an adjoining n⁺-doped layer 18. The substrate 10 may also include further layers which are of no relevance to understanding the present invention and are therefore not illustrated.

A trench capacitor 20 extends from the surface 12 of the substrate 10 perpendicularly through the p-doped layer 16 and into the n⁺-doped layer 18. A narrow and deep trench is substantially completely lined by an insulator or a dielectric, which forms a capacitor dielectric 22, and filled by a metal, which forms an inner capacitor electrode 24 in the region of the n⁺-doped layer 18. The region of the n⁺-doped layer 18 which adjoins the capacitor dielectric 22 forms the outer capacitor electrode 26 of the capacitor 20.

In the region of the p-doped layer 16, the metallic filling of the trench forms a metallic terminal region 28. In other words, the inner capacitor electrode 24 and the metallic terminal region 28 are in a single piece or integral, or they are subregions of the homogeneous metallic filling of the trench which merge into one another.

The insulator layer which forms the capacitor dielectric 22 on one side does not extend all the way to the surface 12 of the substrate. As a result, a metal-semiconductor junction 30 is formed between the metallic terminal region 28 and the semiconductor material of the p-doped layer 16. A thin region, which lies beneath the surface 12 of the substrate 10 and laterally adjoins the metal-semiconductor junction 30, is designated the channel region 32. A gate electrode 34 is arranged above the channel region 32 and is separated from the latter only by the insulator layer 14. A source electrode 36 laterally adjoins the channel region 32. This source electrode lies directly below the surface 12 of the substrate 10 and is formed by an n-doped region within the otherwise p-doped layer 16.

The electrical conductivity of the channel region 32 is dependent on the electrostatic potential of the gate electrode 34. The gate electrode 34 is laterally spaced apart from the metal-semiconductor junction 30, which is referred to as a negative overlap between the gate electrode 34 and the metallic terminal region 28. This negative overlap preferably amounts to between 1 nm and 100 nm, and particularly preferably between 5 nm and 10 nm.

The channel region 32 and the gate electrode 34 form a semiconductor switch for connecting the capacitor 20 to the source electrode 36. The source electrode 36 is simultaneously a bit line or is electrically conductively connected to a bit line. The inner capacitor electrode 24 can be electrically conductively connected to the source electrode 36 by the application of a corresponding potential to the gate electrode 34, in order to enable the capacitor 20 to be charged or discharged. The inner capacitor electrode 24 can be isolated from the source electrode 36 by application of a different potential to the gate electrode 34, so that a charge of the capacitor 20 is retained for a longer time.

A number of different metals with different work functions, for example, platinum, aluminum, copper, copper-aluminum alloys (AlCu), titanium, molybdenum or tungsten, or silicides, such as, for example, CoSi₂, MoSi₂, WSi₂, TaSi₂, TiSi₂, PtSi, PdSi₂, are suitable for use as material for the inner capacitor electrode 24 and the metallic terminal region 28. This additional degree of freedom is preferably utilized in order to optimize the properties of the memory cell 8, in particular to improve the barrier properties of the semiconductor switch, by selecting a metal with a suitable work function and dielectric constant.

FIG. 2 diagrammatically depicts a vertical section through a memory cell 8 in accordance with a second exemplary embodiment of the present invention. This second exemplary embodiment differs from the first exemplary embodiment illustrated in FIG. 1 in terms of the extent of the gate electrode 34 and the design of the metal-semiconductor junction 30. However, the two differences are independent of one another. Consequently, the features of the two exemplary embodiments can be combined with one another as desired.

Unlike the first exemplary embodiment, the second exemplary embodiment illustrated in FIG. 2 has a positive overlap between the gate electrode 34 and the terminal region 28. This positive overlap allows better potential passage and therefore improves in particular the conductivity of the channel region 32 and of the metal-semiconductor junction 30 in the on state. Setting an accurate value for a negative overlap or a positive overlap or also arranging the edge of the gate electrode 34 precisely above the metal-semiconductor junction 30 allows the properties of the memory cell 8, in particular of the semiconductor switch, to be set within wide limits.

Unlike in the first exemplary embodiment illustrated in FIG. 1, the second exemplary embodiment has a tunnel barrier layer 38 between the metallic terminal region 28 and the channel region 32. This tunnel barrier layer 38 reduces the electrical tunnel barrier parameter of the metal-semiconductor junction 30.

It will be clear that the exemplary embodiments of the present invention which are illustrated in FIGS. 1 and 2 can be altered in terms of numerous features. In particular, embodiments of the invention can also be implemented with the doping signs reversed, i.e., with a p⁺-doped layer 18, an n-doped layer 16 and an n-doped source electrode 36.

According to an advantageous variant, only the terminal region 28 is metallic, while the inner capacitor electrode 24 is formed by another conductive material, for example, a doped semiconductor or a metal silicide. The materials of the inner capacitor electrode 24 and of the metallic terminal region 28 then preferably adjoin one another in the region of the layer 16 or merge continuously into one another or merge discontinuously into one another.

Furthermore, the present invention can also be realized using capacitors of other designs, for example, using a capacitor produced by stack technology or a crown-shaped stack capacitor, which is formed above the insulator layer 14 and the gate electrode 34 or in the half-space delimited by the surface 12 of the substrate 10 and remote from the substrate 10.

The semiconductor switch of the memory cell according to the invention can advantageously also be realized as a field-effect transistor, as a multi-gate transistor, as a FinFET, etc.

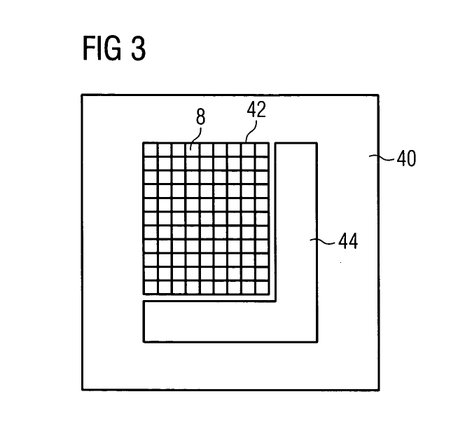

FIG. 3 diagrammatically depicts an integrated memory circuit 40 having a plurality of memory cells 8 which are arranged in one or more arrays 42. The integrated memory circuit 40 also has a control circuit 44, which comprises, inter alia, address or row and column decoders, input and output amplifiers and read amplifiers. The memory cells 8 of the array 42 correspond to the exemplary embodiments explained above with reference to FIGS. 1 and 2, and variants thereof. On account of the improved miniaturization properties of the memory cell according to embodiments of the invention, the integrated memory circuit 40 has a greater number of memory cells 8 and/or a smaller chip surface area.

However, memory cells according to embodiments of the invention can advantageously be used not only in integrated memory circuits but also in any other desired integrated semiconductor circuits.

While the foregoing is directed to embodiments of the present invention, other and further embodiments of the invention may be devised without departing from the basic scope thereof, and the scope thereof is determined by the claims that follow.

What is claimed is:

1. A memory cell for storing data, comprising:
a capacitor with capacitor electrodes for storing electric charge; and
a semiconductor switch with a channel region, the electrical conductivity of which is controllable, for connecting the capacitor to a bit line, via which data can be written to and read from the memory cell,
wherein a metallic terminal region is electrically conductively connected to one of the capacitor electrodes; and
wherein the channel region and the metallic terminal region form a metal-semiconductor junction.

2. The memory cell of claim 1, wherein the metallic terminal region and one of the capacitor electrodes are formed as a single piece.

3. The memory cell of claim 1, further comprising:
a tunnel barrier layer arranged between the metallic terminal region and the channel region.

4. The memory cell of claim 1, further comprising:
a gate electrode for controlling electrical conductivity of the channel region; and
an insulator layer disposed between the channel region and the gate electrode.

5. The memory cell of claim 4, wherein the gate electrode is laterally spaced apart from the metal-semiconductor junction.

6. The memory cell of claim 4, wherein an edge of the gate electrode is arranged above the metal-semiconductor junction.

7. The memory cell of claim 4, wherein the gate electrode laterally overlaps the metallic terminal region.

8. The memory cell of claim 1, wherein the metallic terminal region comprises at least one of Pt, Al, Mo, W, Ti, AlCu and Cu.

9. The memory cell of claim 1, wherein the metallic terminal region comprises at least one silicides selected from CoSi₂, MoSi₂, WSi₂, TaSi₂, TiSi₂, PtSi and PdSi₂.

10. The memory cell of claim 1, wherein the metal-semiconductor junction is a Schottky contact.

11. An integrated semiconductor circuit, comprising:
at least one memory cell for storing data, each memory cell comprising:
a capacitor with capacitor electrodes for storing electric charge; and
a semiconductor switch with a channel region, the electrical conductivity of which is controllable, for connecting the capacitor to a bit line, via which data can be written to and read from the memory cell,
wherein a metallic terminal region is electrically conductively connected to one of the capacitor electrodes; and
wherein the channel region and the metallic terminal region form a metal-semiconductor junction.

12. The circuit of claim 11, wherein the metallic terminal region and one of the capacitor electrodes are formed as a single piece.

13. The circuit of claim 12, wherein each memory cell further comprises:
a tunnel barrier layer arranged between the metallic terminal region and the channel region.

14. The circuit of claim 13, wherein each memory cell further comprises:
a gate electrode for controlling electrical conductivity of the channel region; and
an insulator layer disposed between the channel region and the gate electrode.

15. The circuit of claim 14, wherein the gate electrode is laterally spaced apart from the metal-semiconductor junction.

16. The circuit of claim 14, wherein an edge of the gate electrode is arranged above the metal-semiconductor junction.

17. The circuit of claim 14, wherein the gate electrode laterally overlaps the metallic terminal region.

18. The circuit of claim 11, wherein the metallic terminal region comprises at least one of Pt, Al, Mo, W, Ti, AlCu and Cu, CoSi₂, MoSi₂, WSi₂, TaSi₂, TiSi₂, PtSi and PdSi₂.

19. The circuit of claim 11, wherein the metal-semiconductor junction is a Schottky contact.

20. The circuit of claim 11, wherein the circuit comprises an integrated memory circuit having a plurality of memory cells.

21. A memory cell for storing data, comprising:
a capacitor with capacitor electrodes for storing electric charge;
a semiconductor switch with a channel region, the electrical conductivity of which is controllable, for connecting the capacitor to a bit line, via which data can be written to and read from the memory cell; and
a metallic terminal region, which is electrically conductively connected to one of the capacitor electrodes,
wherein the channel region and the metallic terminal region form a Schottky contact, and
wherein a tunnel barrier layer is arranged between the metallic terminal region and the channel region.

22. The memory cell of claim 21, wherein the memory cell is disposed in an integrated semiconductor circuit.

23. An integrated memory circuit having a plurality of memory cells, each memory cell comprising:
a capacitor with capacitor electrodes for storing electric charge;
a semiconductor switch with a channel region, the electrical conductivity of which is controllable, for connecting the capacitor to a bit line, via which data can be written to and read from the memory cell; and
a metallic terminal region, which is electrically conductively connected to one of the capacitor electrodes,
wherein the channel region and the metallic terminal region form a Schottky contact, and
wherein a tunnel barrier layer is arranged between the metallic terminal region and the channel region.
